(19) United States
(12) Patent Application Publication
(10) Pub. No.: US 2026/0153800 A1
(43) Pub. Date: Jun. 4, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Yunju CHAE, Suwon-si (KR); Miyeon HAN, Suwon-si (KR); Joonhee HAN, Suwon-si (KR); Jimin KIM, Suwon-si (KR); Sumin JANG, Suwon-si (KR); Soobin LIM, Suwon-si (KR); Hyun LEE, Suwon-si (KR); Kyungmog KIM, Suwon-si (KR); Chaeeun LEE, Suwon-si (KR)

(21) Appl. No.: 19/399,462

(22) Filed: Nov. 24, 2025

(30) Foreign Application Priority Data
Nov. 29, 2024 (KR) 10-2024-0175744

(51) Int. Cl. G03F 7/004

(52) U.S. Cl. CPC G03F 7/0045; G03F 7/0042

(57) ABSTRACT

Disclosed are a semiconductor photoresist composition and a method of forming patterns using the same, the semiconductor photoresist composition including an organometallic compound; an aromatic ring compound including a halogen and an electron withdrawing group (EWG) other than a halogen; and a solvent.

### CROSS-REFERENCE TO RELATED APPLICATION

This application claims priority to and the benefit of Korean Patent Application No. 10-2024-0175744 filed at the Korean Intellectual Property Office on Nov. 29, 2024, the entire content of which is hereby incorporated by reference.

### BACKGROUND

### 1. Field

Embodiments of this disclosure relate to a semiconductor photoresist composition and a method of forming patterns using the same.

### 2. Description of the Related Art

EUV (extreme ultraviolet) lithography is paid attention to as one technology for manufacturing a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed in an exposure process during a manufacture of a semiconductor device.

The extreme ultraviolet (EUV) lithography is realized through development of compatible photoresists which can be performed at a spatial resolution of less than or equal to 16 nm. Currently, efforts to satisfy insufficient specifications of traditional chemically amplified (CA) photoresists such as a resolution, a photospeed, and feature roughness (which may also referred to as a line edge roughness or LER) for the next generation device are being made.

An intrinsic image blurring due to an acid catalyzed reaction in these polymer-type photoresists limits a resolution in small feature sizes, which has been present in electron beam (e-beam) lithography for a long time. The chemically amplified (CA) photoresists are designed for high sensitivity, but because their typical elemental makeups reduce light absorbance of the photoresists at a wavelength of 13.5 nm and thus decrease their sensitivity, the chemically amplified (CA) photoresists may at least partially have more difficulties under an EUV exposure.

The CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a high-performance photoresist is desired or required in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism and in addition, is less sensitive about a stochastic effect and thus has low line edge roughness and a small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. More recently, if (e.g., when) cationic hafnium metal oxide sulfate (HfSOx) materials along with a peroxo complexing agent has been used to image a 15 nm half-pitch (HP) through projection EUV exposure, impressive performance has been obtained. This system exhibits the highest performance of a non-CA photoresist and has a practicable photospeed near to a requirement or useful level for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted into molecules including tin that have excellent absorption of extreme ultraviolet rays. As for an organotin polymer among them, alkyl ligands are dissociated by light absorption and/or secondary electrons produced thereby, and are crosslinked with adjacent chains through oxo bonds and thus enable the negative tone patterning which may not be removed by an organic developer. This organotin polymer exhibits greatly improved sensitivity as well as maintains a resolution and line edge roughness, but the patterning characteristics need to be additionally improved for commercial availability.

### SUMMARY

Some example embodiments of the present disclosure provide a semiconductor photoresist composition having excellent resolution characteristics and pattern adhesive strength by reducing the influence of variables during pattern formation and thus improving CD (critical dimension) stability.

Some example embodiments provide a method of forming patterns using the semiconductor photoresist composition.

Some example embodiments provide a semiconductor photoresist composition including an organometallic compound, an aromatic ring compound including a halogen and an electron withdrawing group (EWG) other than a halogen, and a solvent.

A method of forming patterns according to some example embodiments includes providing an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

The method may be performed in an atmosphere having a nitrogen oxide (NOx) concentration of 0.01 ppm or more.

A pattern formed using a semiconductor photoresist composition according to some example embodiments may implement excellent resolution by improving CD stability.

The pattern may have a width of a thickness of about 5 nm to about 100 nm.

The pattern is formed in an atmosphere having a nitrogen oxide (NOx) concentration of 0.01 ppm or more.

The photoresist pattern has a CD change (ΔCD(%)) of 1.20 or less, as calculated by the following equation:

$$Δ CD \% = ( {CD}_{\geq 0.01 ppm NOx} / {CD}_{w / o NOx} ) , \qquad [ Equation ]$$

wherein, in the Equation, CD_{≥0.01 ppm NOx} is the critical dimension of the photoresist pattern when the photoresist pattern is formed in an atmosphere having an NOx concentration of 0.01 ppm or more, and CD_{w/o NOx} is the critical dimension of the photoresist pattern when the photoresist pattern is formed in an atmosphere having no NOx.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E are cross-sectional views illustrating a method of forming patterns using a semiconductor photoresist composition according to some example embodiments.

### DETAILED DESCRIPTION

Hereinafter, referring to the drawings, embodiments are described in more detail. In the following description of the present disclosure, the well-known functions or constructions will not be described in order to clarify the present disclosure.

In order to clearly illustrate embodiments of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, and/or the like, may be exaggerated for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a carboxyl group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “aryl group” refers to a substituent in which all atoms in the cyclic substituent have a p-orbital and these p-orbitals are conjugated and may include a monocyclic or fused ring polycyclic functional group (e.g., a functional group including rings sharing adjacent pairs of carbon atoms).

As used herein, “heteroaryl group” may refer to an aryl group including at least one heteroatom selected from N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to some example embodiments is described.

A semiconductor photoresist composition according to some example embodiments includes an organometallic compound, a linear carboxylic acid compound, a cyclic carboxylic acid compound represented by Chemical Formula 1, and a solvent.

A method of forming patterns by using a semiconductor photoresist composition including an organometallic compound includes coating the photoresist composition on an etching-objective layer, so that the organometallic compound or its cluster molecules in the photoresist composition may be coated on the etching-objective layer, and then, proceeding with a first baking process, an exposure process, a second baking process, and a development process to remove an organic material in the photoresist composition and thus to pattern a metal oxide.

In embodiments, the patterning of the metal oxide is affected by various suitable variables such as a temperature, a solvent, a concentration, a catalyst, an atmosphere, and/or the like, and, for example, the smaller pattern size, the relatively larger the resultant effect. For example, because a pattern formed by a photoresist composition including an organometallic compound has a very small size in a range of from several nm to several tens of nm, the metal oxide-patterning may be more affected by the process conditions than a photoresist that does not include an organometallic compound.

For example, the pattern formation by a photoresist composition including an organometallic compound is affected by a concentration of nitrogen oxide (NOx) in the atmosphere. NOx is a highly reactive substance that exists in the atmosphere and may react with moisture, sunlight, and/or the like in the atmosphere to cause phenomena such as smog and/or the like, wherein if (e.g., when) the concentration of NOx exceeds a set or predetermined level, there is a problem that a pattern width and/or the like, which are checked after the development, differ from target values.

Accordingly, in embodiments of the present disclosure, by introducing an aromatic ring compound having an electron withdrawing group (EWG) other than a halogen, sensitivity to extreme ultraviolet rays can be increased and pattern roughness can be improved. In embodiments, a photoresist composition is capable of reducing reactivity of the central metal toward radicals by additionally introducing a halogen to the aromatic ring compound so that it may be coordinated to the central metal of the organometallic compound, and also capable of suppressing or reducing the deformation of pattern width caused by NOx by stabilizing radicals resulting from NOx and lowering the reactivity with the radicals.

The aromatic ring compound including the halogen and an electron withdrawing group other than halogen may be represented by Chemical Formula 1.

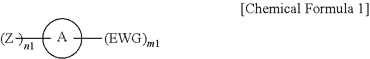

In Chemical Formula 1,
Z is a halogen,
EWG is an electron withdrawing group,
A is a substituted or unsubstituted C6 to C20 aromatic ring,
n1 and m1 are each independently an integer of greater than or equal to 1, and
n1+m1 is an integer of less than or equal to the valence of A.

A may have various suitable modifications, such as being a divalent group, a trivalent group, or a tetravalent group, depending on the number of connected substituents.

For example, A may be a substituted or unsubstituted benzene group, a substituted or unsubstituted naphthalene group, a substituted or unsubstituted anthracene group, a substituted or unsubstituted phenanthrene group, a substituted or unsubstituted pyrene group, a substituted or unsubstituted triphenylene group, or a combination thereof.

For example, Z may be at least one selected from fluoro, chloro, and iodo.

The electron withdrawing group is a group which by itself withdraws electron density from adjacent atoms by resonance (e.g., an electron resonance effect), inductive (e.g., induction), hyperconjugation or a combination thereof, and may include a weak electron withdrawing group, such as a halogen; a moderate electron withdrawing group, such as an aldehyde group, a carbonyl-containing group, a carboxyl group, an ester group, or an amide group; or a strong electron withdrawing group, such as a trihalide group, a cyano group, a sulfone group, a sulfonate group, or a nitro group.

For example, the electron withdrawing group may include or be a cyano group, a cyano-containing group, a nitro group, an amino group, an ammonium group, an amidino group, a C1 to C10 alkylamine group, a C6 to C20 arylamine group, a C7 to C20 arylalkylamine group, a C1 to C10 carboxyl group, an ester group, a C1 to C10 alkyl group substituted with a carbonyl group, a C2 to C10 heteroalkyl group substituted with a carbonyl group, a C6 to C14 aryl group substituted with a carbonyl group, a C2 to C10 heteroaryl group substituted with a carbonyl group, an amide group, a sulfone group, a sulfonate group, or a C2 to C30 N-containing heteroaryl group.

As an example, the electron withdrawing group may include or be a cyano group, a nitro group, an amino group, an ammonium group, a C1 to C6 alkylamine group, a C6 to C12 arylamine group, a C7 to C12 arylalkylamine group, or a sulfonate group.

In some example embodiments, Chemical Formula 1 may be represented by any one selected from Chemical Formula 1-1 to Chemical Formula 1-3.

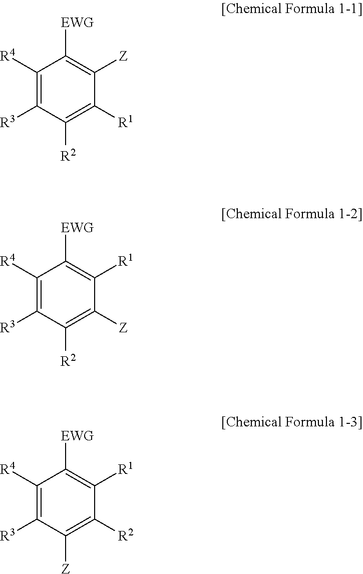

In Chemical Formula 1-1 to Chemical Formula 1-3, PP-23,C1
Z is a halogen,
EWG is an electron withdrawing group, and
R¹ to R⁴ are each independently hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group.

In some example embodiments, R¹ to R⁴ may each independently be hydrogen, a halogen, a hydroxy group, a substituted or unsubstituted C1 to C10 alkyl group, or a substituted or unsubstituted C6 to C20 aryl group.

In some example embodiments, R¹ to R⁴ may each independently be hydrogen, a halogen, a hydroxy group, a substituted or unsubstituted C1 to C5 alkyl group, or a substituted or unsubstituted C6 to C12 aryl group.

For example, R¹ to R⁴ may each independently be hydrogen, a halogen, a hydroxy group, a substituted or unsubstituted methyl group, a substituted or unsubstituted ethyl group, a substituted or unsubstituted propyl group, a substituted or unsubstituted iso-propyl group, a substituted or unsubstituted butyl group, a substituted or unsubstituted sec-butyl group, a substituted or unsubstituted iso-butyl group, a substituted or unsubstituted tert-butyl group, a substituted or unsubstituted phenyl group, or a combination thereof.

For example, the aromatic ring compound including the halogen and the electron withdrawing group other than the halogen may be selected from the compounds listed in Group 1.

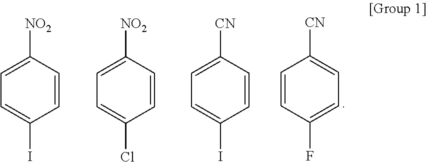

The aromatic ring compound including the halogen and an electron withdrawing group other than halogen may be included in an amount of about 0.01 to about 25 wt % based on 100 wt % of the semiconductor photoresist composition.

For example, the aromatic ring compound including the halogen and the electron withdrawing group other than the halogen may be included in an amount of about 0.01 to about 20 wt %, about 0.01 to about 10 wt %, about 0.02 to about 10 wt %, about 0.03 to about 10 wt %, or about 0.05 to about 10 wt % based on 100 wt % of the semiconductor photoresist composition.

The organometallic compound may be included in an amount of about 0.5 wt % to about 30 wt % based on 100 wt % of the semiconductor photoresist composition.

The semiconductor photoresist composition according to some example embodiments can improve the sensitivity of the photoresist by including the aromatic ring compound including the halogen and the electron withdrawing group other than the halogen within the above content ranges.

The organometallic compound may be an organotin compound including at least one selected from an organic oxy group and an organic carbonyloxy group.

The organometallic compound may be represented by Chemical Formula 2.

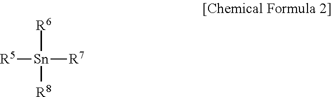

In Chemical Formula 2,
R⁵ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R⁶ to R⁸ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one of selected from R⁶ to R⁸ is selected from alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (-NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

At least one selected from R⁶ to R⁸ may be selected from alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In embodiments, because the compound represented by Chemical Formula 2 includes —OR^{b} or —OC(═O)R^{c} as a ligand, a pattern formed using a semiconductor photoresist composition including the compound may exhibit excellent limit resolution.

In embodiments, the ligand of —OR^{b} or —OC(═O)R^{c} may determine the solubility of the compound represented by Chemical Formula 2 in a solvent.

R⁵ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R⁵ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In embodiments, the organometallic compound may be represented by Chemical Formula 3 or Chemical Formula 4.

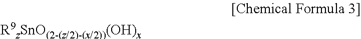

In Chemical Formula 3,
R⁹ is a C1 to C31 hydrocarbyl group, 0<z≤2, and 0<(z+x)≤4;

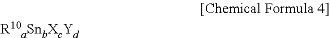

wherein, in Chemical Formula 4,
R¹⁰ is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

The solvent included in the semiconductor photoresist composition according to some example embodiments may be an organic solvent, and may be for example aromatic compounds (e.g., xylene, toluene, and/or the like), alcohols (e.g., 4-methyl-2-pentenol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but is not limited thereto.

The semiconductor resist composition according to some example embodiments may further include a resin in addition to the aforementioned organometallic compound, the aromatic ring compound including the halogen and an electron-withdrawing group other than the halogen, and the solvent.

The resin may be a phenol-based resin including at least one aromatic moiety listed in Group 2.

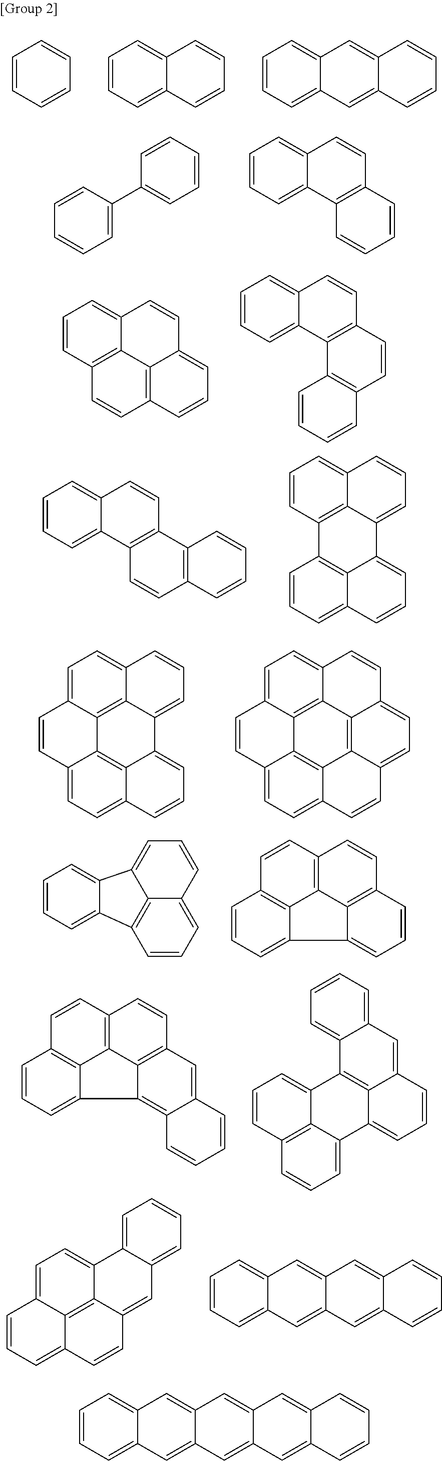

The resin may have a weight average molecular weight of about 500 to about 20,000 (e.g., about 500 to about 20,000 daltons or g/mol).

The resin may be included in an amount of about 0.1 wt % to about 50 wt % based on a total amount of the semiconductor photoresist composition.

If the resin is included in the above amount range, it may have excellent etch resistance and heat resistance.

In embodiments, the semiconductor photoresist composition may be composed of the aforementioned organometallic compound, the aromatic ring compound including the halogen and the electron withdrawing group other than the halogen, solvent, and resin.

The semiconductor photoresist composition according to the aforementioned embodiments may further include additives as needed. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve coating flatness during printing and may be any suitable commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-tolyl) amine, methyl diphenyl amine, triphenyl amine, phenylenediamine, naphthylamine, diaminonaphthalene, or a combination thereof.

Each use amount of the additives may be controlled depending on suitable or desired properties of the semiconductor photoresist composition.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(p-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or, for example, about 5 nm to about 20 nm, the semiconductor photoresist composition may be used for a photoresist process using light in a wavelength range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source that emits light having a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes providing an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

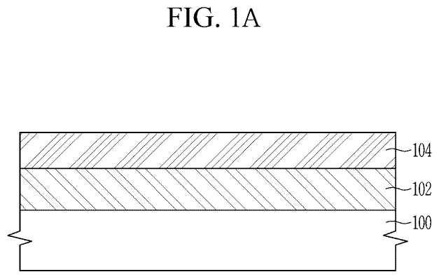

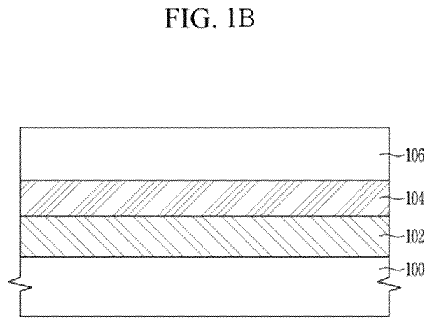

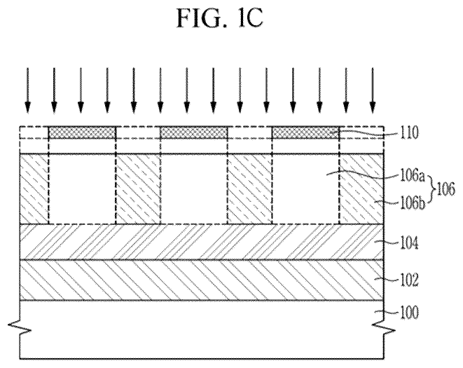

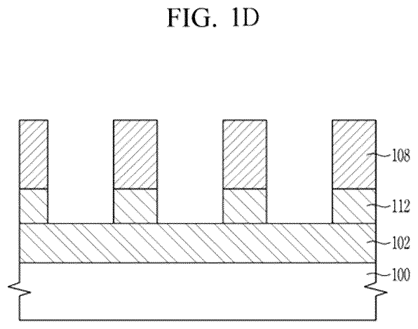

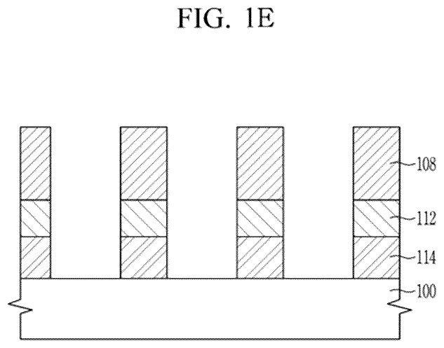

Hereinafter, a method of forming patterns using the semiconductor photoresist composition is described referring to FIGS. 1A-1E. FIGS. 1A-1E are cross-sectional views illustrating a method of forming patterns using a semiconductor photoresist composition according to some example embodiments.

Referring to FIG. 1A, an object for etching is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, embodiments are not limited thereto, and various suitable coating methods, for example, a spray coating, a dip coating, a knife edge coating, a printing method, for example, an inkjet printing and/or a screen printing, and/or the like may be used.

The coating process of the resist underlayer may be omitted, and hereinafter, a process including a coating of the resist underlayer is described.

The coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity and improve pattern formability of a photoresist line width if (e.g., when) a ray reflected from the interface between the substrate 100 and the photoresist film 106 and/or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist film 106.

The semiconductor photoresist composition has already been illustrated in detail and duplicative description thereof may not be repeated here.

Subsequently, a substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation including light having a high energy wavelength light such as EUV (extreme ultraviolet; a wavelength of about 13.5 nm), an E-Beam (an electron beam), and/or the like as well as light having a wavelength such as an i-line (a wavelength of about 365 nm), a KrF excimer laser (a wavelength of about 248 nm), an ArF excimer laser (a wavelength of about 193 nm), and/or the like.

In embodiments, light for the exposure according to some example embodiments may be light having a wavelength range from about 5 nm to about 150 nm and a high energy wavelength, for example, EUV (extreme ultraviolet; a wavelength of 13.5 nm), an E-Beam (an electron beam), and/or the like.

The exposed region 106b of the photoresist film 106 has a different solubility from the unexposed region 106a of the photoresist film 106 by forming a polymer by a crosslinking reaction such as condensation (e.g., a condensation reaction) between organometallic compounds.

Subsequently, the substrate 100 is subjected to a second baking process. The second baking process may be performed at a temperature of about 90° C. to about 200° C. The exposed region 106b of the photoresist film 106 becomes indissoluble with respect to a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be, for example, ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some example embodiments is not necessarily limited to the negative tone image but may be formed to have a positive tone image. In embodiments, a developer used to form the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a shorter energy such as i-line (wavelength of about 365 nm), KrF excimer laser (wavelength of about 248 nm), ArF excimer laser (wavelength of about 193 nm), and/or the like may provide a photoresist pattern 108 having a width of about 5 nm to about 100 nm. For example, the photoresist pattern 108 may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch having a half-pitch of less than or equal to about 50 nm, for example, less than or equal to about 40 nm, for example, less than or equal to about 30 nm, for example, less than or equal to about 20 nm, or, for example, less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

40.7 g of t-butylSnPh₃ and 300 g of propionic acid were added to a 250 ml two-necked round-bottom flask and heated under reflux for 24 hours.

Unreacted propionic acid was removed under reduced pressure to obtain a compound represented by Chemical Formula 5.

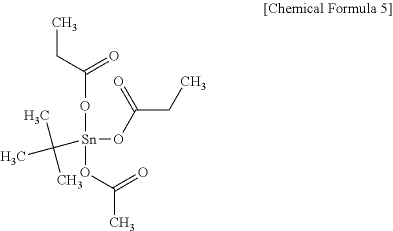 [SMILES: CCC(=O)[O][Sn]([O]C(C)=O)([O]C(=O)CC)[C](C)(C)C]

### Synthesis Example 2

30 ml of anhydrous pentane was added to 10 g of t-AmylSnCl₃, the temperature was maintained at 0° C., and then 7.4 g of diethylamine and 6.1 g of ethanol were added thereto, and stirred at room temperature for 1 hour. When the reaction was completed, the resultant was filtered, concentrated and vacuum-dried to obtain a compound represented by Chemical Formula 6.

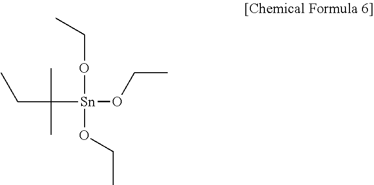

### Synthesis Example 3

10 g of dibutyltin dichloride was dissolved 30 mL of ether, 70 mL of a 1 M sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500.

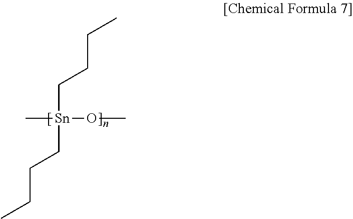

### Preparation of Semiconductor Photoresist Compositions

### Examples 1 to 14 and Comparative Examples 1 to 4

The organometallic compounds represented by Chemical Formula 5 to Chemical Formula 7 (in the amounts shown in Table 1) obtained in Synthesis Examples 1 to 3, and the aromatic ring compounds A1 to A4 including halogen and EWG other than halogen or trifluoroacetic acid as additive (in the amounts shown in Table 1) were each dissolved in propylene glycol methyl ether acetate (PGMEA) to provide a total concentration of 3 wt % (e.g., total concentration of the organometallic compounds represented by Chemical Formula 5 to Chemical Formula 7 and the additive or aromatic ring compounds A1 to A4 including halogen and EWG other than halogen (if any)), and then filtered through a 0.1 μm PTFE (polytetrafluoroethylene) syringe filter, thereby preparing the semiconductor photoresist compositions according to Examples 1 to 14 and Comparative Examples 1 to 4.

TABLE 1

| | Organometallic compound | |
|---|---|---|
| | (wt %) | Additive (wt %) |
| Comparative | Chemical Formula 5 (3.0) | — |
| Example 1 | | |
| Comparative | Chemical Formula 5 (2.5) | trifluoroacetic |
| Example 2 | | acid (0.5) |
| Example 1 | Chemical Formula 5 (2.5) | A1 (0.5) |
| Example 2 | Chemical Formula 5 (2.5) | A2 (0.5) |
| Example 3 | Chemical Formula 5 (2.5) | A3 (0.5) |
| Example 4 | Chemical Formula 5 (2.5) | A4 (0.5) |
| Comparative | Chemical Formula 6 (3.0) | — |
| Example 3 | | |
| Example 5 | Chemical Formula 6 (2.5) | A1 (0.5) |
| Example 6 | Chemical Formula 6 (2.5) | A2 (0.5) |
| Example 7 | Chemical Formula 6 (2.5) | A3 (0.5) |
| Example 8 | Chemical Formula 6 (2.5) | A4 (0.5) |
| Comparative | Chemical Formula 7 (3.0) | — |
| Example 4 | | |
| Example 9 | Chemical Formula 7 (2.5) | A1 (0.5) |
| Example 10 | Chemical Formula 7 (2.5) | A2 (0.5) |
| Example 11 | Chemical Formula 7 (2.5) | A3 (0.5) |
| Example 12 | Chemical Formula 7 (2.5) | A4 (0.5) |
| Example 13 | Chemical Formula 5 (2.75) | A4 (0.25) |
| Example 14 | Chemical Formula 5 (2.3) | A4 (0.7) |

[Aromatic Ring Compounds Including Halogen and EWG Other than Halogen]
A1: 1-iodo-4-nitrobenzene, A2: 1-chloro-4-nitrobenzene,
A3: 4-iodobenzonitrile, A4: 4-fluorobenzonitrile

### Evaluation: Evaluation of CD Uniformity and Pattern Adhesive Strength

Each of the resist compositions for a semiconductor according to Examples to 14 and Comparative Examples 1 to 4 was spin-coated on a 200 mm circular silicon wafer at 1500 rpm for 30 seconds and then, heated at 110° C. for 60 seconds.

Subsequently, a linear array having a line width of 180 nm was projected onto the wafer coated with the resist composition for a photoresist by using KrF light. Then, the resist and the substrate were heated at 180° C. on a hot plate for 120 seconds. The baked film was developed using a PGMEA solvent to form a negative tone image. Finally, the baking at 200° C. for 180 seconds were performed to complete the process.

The resists were measured with respect to CD values when there was no NOx (or no detectable NOx) in the atmosphere and when NOx was at a concentration of 0.01 ppm or more by using critical dimension-scanning electron microscopy (CD-SEM), which were used to calculate a CD change (ΔCD(%)), and the results are shown in Table 2. The NOx concentration was measured by using a Sky2000-NOx detector (Safegas). The CD change was calculated according to the following equation.

$$Δ CD \% = ( {CD}_{\geq 0.01 ppm NOx} / {CD}_{w / o NOx} ) \qquad [ Equation ]$$

As for the pattern images evaluated using CD-SEM, if even a portion of the pattern in a region of 15 μm×15 μm was chipped or disappeared, it was judged to be ‘X’, and if all of the pattern was present, it was judged to be ‘o’ and the results are shown in Table 2.

TABLE 2

| | CD uniformity (%) | Pattern adhesive strength |
|---|---|---|
| Comparative Example 1 | 1.42 | X |
| Comparative Example 2 | 1.3 | X |
| Example 1 | 1.11 | ◯ |
| Example 2 | 1.14 | ◯ |
| Example 3 | 1.18 | ◯ |
| Example 4 | 1.19 | ◯ |
| Comparative Example 3 | 1.28 | X |
| Example 5 | 1.14 | ◯ |
| Example 6 | 1.03 | ◯ |
| Example 7 | 1.15 | ◯ |
| Example 8 | 1.08 | ◯ |
| Comparative Example 4 | 1.46 | X |
| Example 9 | 1.16 | ◯ |
| Example 10 | 1.14 | ◯ |
| Example 11 | 1.05 | ◯ |
| Example 12 | 1.14 | ◯ |
| Example 13 | 1.15 | ◯ |
| Example 14 | 0.96 | ◯ |

Referring to the results of Table 2, the patterns formed of the photoresist compositions for a semiconductor according to Examples 1 to 14 exhibited excellent resistance to NOx influence, excellent pattern uniformity, and excellent pattern adhesive strength compared to Comparative Examples 1 to 4.

Hereinbefore, certain embodiments of the present disclosure have been described and illustrated, however, it should be apparent to a person having ordinary skill in the art that the present disclosure is not limited to the embodiments as described, and may be variously, suitably modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

### DESCRIPTION OF SYMBOLS

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound;
an aromatic ring compound comprising a halogen and an electron withdrawing group (EWG) other than a halogen; and
a solvent.

2. The semiconductor photoresist composition as claimed in claim 1, wherein:
the aromatic ring compound comprising the halogen and the electron withdrawing group other than the halogen is represented by Chemical Formula 1: 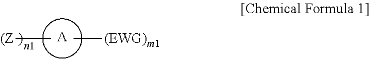
wherein, in Chemical Formula 1,
Z is a halogen,
EWG is the electron withdrawing group,
A is a substituted or unsubstituted C6 to C20 aromatic ring,
n1 and m1 are each independently an integer of greater than or equal to 1, and
n1+m1 is an integer of less than or equal to the valence of A.

3. The semiconductor photoresist composition as claimed in claim 2, wherein:
A is a substituted or unsubstituted benzene group, a substituted or unsubstituted naphthalene group, a substituted or unsubstituted anthracene group, a substituted or unsubstituted phenanthrene group, a substituted or unsubstituted pyrene group, a substituted or unsubstituted triphenylene group, or a combination thereof.

4. The semiconductor photoresist composition as claimed in claim 1, wherein:
the electron withdrawing group comprises a cyano group, a cyano-containing group, a nitro group, an amino group, an ammonium group, an amidino group, a C1 to C10 alkylamine group, a C6 to C20 arylamine group, a C7 to C20 arylalkylamine group, a C1 to C10 carboxyl group, an ester group, a C1 to C10 alkyl group substituted with a carbonyl group, a C2 to C10 heteroalkyl group substituted with a carbonyl group, a C6 to C14 aryl group substituted with a carbonyl group, a C2 to C10 heteroaryl group substituted with a carbonyl group, an amide group, a sulfone group, a sulfonate group, or a C2 to C30 N-containing heteroaryl group.

5. The semiconductor photoresist composition as claimed in claim 1, wherein:
the electron withdrawing group comprises a cyano group, a nitro group, an amino group, an ammonium group, a C1 to C6 alkylamine group, a C6 to C12 arylamine group, a C7 to C12 arylalkylamine group, or a sulfonate group.

6. The semiconductor photoresist composition as claimed in claim 2, wherein:
Chemical Formula 1 is represented by any one selected from Chemical Formula 1-1 to Chemical Formula 1-3: 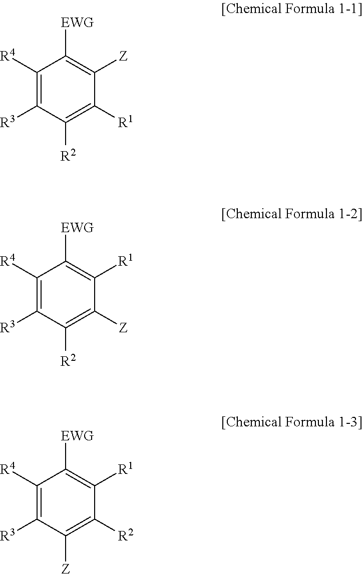
wherein, in Chemical Formula 1-1 to Chemical Formula 1-3,
Z is a halogen,
EWG is the electron withdrawing group, and
R¹ to R⁴ are each independently hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group.

7. The semiconductor photoresist composition as claimed in claim 1, wherein:
the aromatic ring compound comprising the halogen and the electron withdrawing group other than the halogen is one selected from the compounds listed in Group 1:

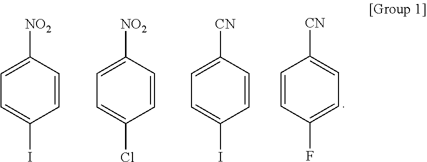

8. The semiconductor photoresist composition as claimed in claim 1, wherein:
the aromatic ring compound comprising the halogen and the electron withdrawing group other than the halogen is included in an amount of about 0.01 to about 25 wt % based on 100 wt % of the semiconductor photoresist composition.

9. The semiconductor photoresist composition as claimed in claim 1, wherein:
the organometallic compound is included in an amount of about 0.5 wt % to about 30 wt % based on 100 wt % of the semiconductor photoresist composition.

10. The semiconductor photoresist composition as claimed in claim 1, wherein:
the semiconductor photoresist composition further comprises an additive comprising a surfactant, a crosslinking agent, a leveling agent, an organic acid, a quencher, or a combination thereof.

11. The semiconductor photoresist composition as claimed in claim 1, wherein:
the organometallic compound comprises at least one selected from an organic oxy group and an organic carbonyloxy group.

12. The semiconductor photoresist composition as claimed in claim 1, wherein:
the organometallic compound is represented by Chemical Formula 2: 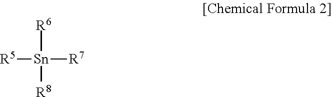
wherein, in Chemical Formula 2,
R⁵ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R⁶ to R⁸ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from R⁶ to R⁸ is selected from alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

13. The semiconductor photoresist composition as claimed in claim 12, wherein:
at least one selected from R⁶ to R⁸ is selected from alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

14. The semiconductor photoresist composition as claimed in claim 13, wherein:
R⁵ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or combination thereof.

15. The semiconductor photoresist composition as claimed in claim 1, wherein:
the organometallic compound is represented by Chemical Formula 3 or Chemical Formula 4: 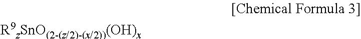
wherein, in Chemical Formula 3,
R⁹ is a C1 to C31 hydrocarbyl group, 0<z≤2, and 0<(z+x)≤4; 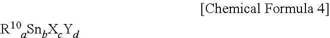
wherein, in Chemical Formula 4,
R¹⁰ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, ethylene oxide group, propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

16. A method of forming patterns, comprising:
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer using the photoresist pattern as an etching mask.

17. The method as claimed in claim 16, wherein the method is performed in an atmosphere having a nitrogen oxide (NOx) concentration of 0.01 ppm or more.

18. A photoresist pattern formed according to the method as claimed in claim 16, wherein the photoresist pattern has a width of a thickness of about 5 nm to about 100 nm.

19. A photoresist pattern formed according to the method as claimed in claim 16, wherein the photoresist pattern is formed in an atmosphere having a nitrogen oxide (NOx) concentration of 0.01 ppm or more.

20. A photoresist pattern formed according to the method as claimed in claim 16, wherein the photoresist pattern has a CD change of 1.20 or less, wherein the CD change is ΔCD(%), as calculated by the following equation:
$$Δ CD \% = ( {CD}_{\geq 0.01 ppm NOx} / {CD}_{w / o NOx} ) , \qquad [ Equation ]$$
wherein, in the Equation, CD_{≥0.01 ppm NOx} is the critical dimension of the photoresist pattern when the photoresist pattern is formed in an atmosphere having a nitrogen oxide concentration of 0.01 ppm or more, and CD_{w/o NOx} is the critical dimension of the photoresist pattern when the photoresist pattern is formed in an atmosphere having no NOx.
